(19) United States
(12) Patent Application Publication
(10) Pub. No.: US 2025/0189881 A1
(43) Pub. Date: Jun. 12, 2025

(54) LITHOGRAPHIC PATTERN REPRESENTATION WITH CURVILINEAR ELEMENTS

(71) Applicant: ASML NETHERLANDS B.V., Veldhoven (NL)

(72) Inventors: Ya LUO, Saratoga, CA (US); Yen-Wen LU, Saratoga, CA (US); Been-Der CHEN, Milpitas, CA (US); Rafael C. HOWELL, Santa Clara, CA (US); Quan ZHANG, San Jose, CA (US); Zhangnan ZHU, San Jose, CA (US); Xiaoshuang CHEN, Campbell, CA (US)

(73) Assignee: ASML NETHERLANDS B.V., Veldhoven (NL)

(21) Appl. No.: 18/843,541

(22) PCT Filed: Feb. 28, 2023
(86) PCT No.: PCT/EP2023/055028

§ 371 Date: Sep. 3, 2024

Related U.S. Application Data
(60) Provisional application No. 63/322,517, filed on Mar. 22, 2022.

(51) Int. Cl. G03F 1/36; G03F 1/70; G03F 7/00

(52) U.S. Cl. CPC G03F 1/36; G03F 1/70; G03F 7/70441; G03F 7/705

(57) ABSTRACT

Methods, systems, and computer software are disclosed for determining a mask pattern for use with a lithographic process. One method includes assigning locations of two-dimensional elements based on a target pattern, associating the two-dimensional elements based on association criteria to form a cluster that represents a mask feature, and adjusting the two-dimensional elements of the cluster to vary the mask feature.

### CROSS-REFERENCE TO RELATED APPLICATIONS

This application claims priority of U.S. application 63/322,517 which was filed on Mar. 22, 2022 and which is incorporated herein in its entirety by reference.

### TECHNICAL FIELD

The description herein relates generally to lithographic manufacturing and patterning processes. More particularly, related to mask pattern determination.

### BACKGROUND

A lithographic projection apparatus can be used, for example, in the manufacture of integrated circuits (ICs). In such a case, a patterning device (e.g., a mask) may contain or provide a pattern corresponding to an individual layer of the IC (“design layout”), and this pattern can be transferred onto a target portion (e.g., comprising one or more dies) on a substrate (e.g., silicon wafer) that has been coated with a layer of radiation-sensitive material (“resist”), by methods such as irradiating the target portion through the pattern on the patterning device. In general, a single substrate contains a plurality of adjacent target portions to which the pattern is transferred successively by the lithographic projection apparatus, one target portion at a time. In one type of lithographic projection apparatuses, the pattern on the entire patterning device is transferred onto one target portion in one go; such an apparatus may also be referred to as a stepper. In an alternative apparatus, a step-and-scan apparatus can cause a projection beam to scan over the patterning device in a given reference direction (the “scanning” direction) while synchronously moving the substrate parallel or anti-parallel to this reference direction. Different portions of the pattern on the patterning device are transferred to one target portion progressively. Since, in general, the lithographic projection apparatus will have a reduction ratio M (e.g., 4), the speed F at which the substrate is moved will be 1/M times that at which the projection beam scans the patterning device. More information with regard to lithographic devices can be found in, for example, U.S. Pat. No. 6,046,792, incorporated herein by reference.

Prior to transferring the pattern from the patterning device to the substrate, the substrate may undergo various procedures, such as priming, resist coating and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish off the individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

Thus, manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc.

As noted, lithography is a central step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced while the amount of functional elements, such as transistors, per device has been steadily increasing over decades, following a trend referred to as “Moore's law.” At the current state of technology, layers of devices are manufactured using lithographic projection apparatuses that project a design layout onto a substrate using illumination from a deep-ultraviolet illumination source, creating individual functional elements having dimensions well below 100 nm, i.e. less than half the wavelength of the radiation from the illumination source (e.g., a 193 nm illumination source).

This process in which features with dimensions smaller than the classical resolution limit of a lithographic projection apparatus are printed, is can be referred to as low-k1 lithography, according to the resolution formula CD=k1×λ/NA, where λ is the wavelength of radiation employed (e.g., 248 nm or 193 nm), NA is the numerical aperture of projection optics in the lithographic projection apparatus, CD is the “critical dimension”—generally the smallest feature size printed—and k1 is an empirical resolution factor. In general, the smaller k1 the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET). The term “projection optics” as used herein should be broadly interpreted as encompassing various types of optical systems, including refractive optics, reflective optics, apertures and catadioptric optics, for example. The term “projection optics” may also include components operating according to any of these design types for directing, shaping or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

### SUMMARY

Methods, systems, and computer software are disclosed for determining a mask pattern for use with a lithographic process. In one aspect, the method can include assigning locations of two-dimensional elements based on a target pattern, associating the two-dimensional elements based on association criteria to form a cluster that represents a mask feature, and adjusting the two-dimensional elements of the cluster to vary the mask feature.

In some variations, the adjusting can be based on a simulation associated with the lithography process or can be based on geometric properties of the mask pattern and based on rules prescribed for OPC.

In other variations, the method can include generating a contour of the cluster based on the two-dimensional elements. The contour can be an outer contour of the cluster that corresponds to an outer edge of the mask feature or an inner contour of the cluster that corresponds to an inner edge of the mask feature. The method can also include generating sub-areas of the contour by applying a polygon offsetting operation to pairs of the associated two-dimensional elements and computing the union of the sub-areas, wherein the contour is the union of the sub-areas. The method can also include manufacturing a mask from the mask pattern that includes the contour generated from the adjusted two-dimensional elements.

In yet other variations, the contour can be at least partially a prescribed distance from the locations of the two-dimensional elements or can be entirely at least the prescribed distance from the locations of the two-dimensional elements. The prescribed distance can be based on an MRC rule for a minimum width of the mask feature. In some embodiments, at least a portion of the contour can violate an MRC rule. Also, the geometry of the two-dimensional elements can be defined based on one or more mask rule compliance (MRC) rules. A dimension parameter of the two-dimensional element can be selected to be a minimum width specified by the MRC rules. One or more MRC rules can include a minimum space requirement, the association criteria comprising connecting a second two-dimensional element into the cluster when a distance between a second contour for the second two-dimensional element and the contour for the two-dimensional elements in the cluster is less than the minimum space requirement.

In some variations, the method can include modifying the cluster of the two-dimensional elements into one or more modified clusters. The modified clusters can be formed based on MRC rules. The method can also include modifying the cluster by dissociating one of the two-dimensional elements from the cluster and modifying the contour based on the modified cluster. Also, the method can include modifying the cluster by associating a two-dimensional element from another cluster with the cluster and modifying the contour based on the modified cluster.

In other variations, the adjusting can include optimizing the mask pattern by moving a location of one or more of the two-dimensional elements or the adjusting can include optimizing the mask pattern by adjusting a size or a shape of one or more of the two-dimensional elements. The associating can include associating a two-dimensional element that is within a prescribed distance from other two-dimensional elements. The associating or adjusting can also include dissociating a two-dimensional element from the two-dimensional elements of the cluster and associating the two-dimensional element with a two-dimensional element in a second cluster.

In yet other variations, the method can include computing a cost function that quantifies an evaluation of the mask pattern, where the adjusting of the two-dimensional elements is based on the cost function. The cost function may not include any terms based on MRC rules.

In some variations, each of the two-dimensional elements can be circular, elliptical, the same size, define a non-zero area, is a polygon, or defines an enclosed or semi-enclosed area.

In other variations, the method can include performing corner rounding on the outer contour. The corner rounding can include performing spline interpolation between two points on either side of a corner.

In yet other variations, the method can include generating consistent clusters by replicating the cluster in the mask pattern and adjusting corresponding two-dimensional elements in the consistent clusters. The adjusting of the consistent clusters can include identifying a boundary two-dimensional element across a boundary between a first mask patch and a second mask patch, where adjusting the two-dimensional elements excludes adjusting the boundary two-dimensional element. The adjusting of the consistent clusters can also include designating the two-dimensional elements that are within a threshold distance of a boundary of a first mask patch and a second mask patch as priority two-dimensional elements, where adjusting the two-dimensional elements excludes adjusting any priority two-dimensional elements. The method can include storing, in computer memory for later recall, the priority two-dimensional elements. The method can also include replacing one or more of the two-dimensional elements within the threshold distance to the boundary with priority two-dimensional elements.

In some variations, the method can include receiving the mask pattern, generating consistent clusters by replicating the cluster in the mask pattern, where the adjusting includes adjusting corresponding two-dimensional elements in the consistent clusters, designating the two-dimensional elements that are within a threshold distance of a boundary of a first mask patch and a second mask patch as priority two-dimensional elements, replacing one or more of the two-dimensional elements close to the boundary with priority two-dimensional elements recalled from computer memory, and generating an adjusted mask pattern based on the two-dimensional elements in the consistent clusters, wherein adjusting the two-dimensional elements excludes adjusting any priority two-dimensional elements.

In some embodiments, there can be a non-transitory computer readable medium having instructions recorded thereon for determining a mask pattern for use with a lithographic process, the instructions when executed by a computer having at least one programmable processor cause operations comprising any of the operations in the above method embodiments.

In some embodiments, there can be a system for determining a mask pattern for use with a lithographic process, the system comprising: at least one programmable processor; and a non-transitory computer readable medium having instructions recorded thereon, the instructions when executed by a computer having the at least one programmable processor cause operations comprising any of the operations in the above method embodiments.

### BRIEF DESCRIPTION OF THE DRAWINGS

The accompanying drawings, which are incorporated in and constitute a part of this specification, show certain aspects of the subject matter disclosed herein and, together with the description, help explain some of the principles associated with the disclosed implementations. In the drawings,

FIG. 1 illustrates a block diagram of various subsystems of a lithographic projection apparatus, according to an embodiment of the present disclosure.

FIG. 2 illustrates an exemplary flow chart for simulating lithography in a lithographic projection apparatus, according to an embodiment of the present disclosure.

FIG. 3 illustrates an exemplary mask pattern and mask features.

FIG. 4 illustrates a conventional mask feature generated with OPC violating MRC rules.

FIG. 5 illustrates exemplary process for placing, associating, and adjusting two-dimensional elements forming a mask feature, according to an embodiment of the present disclosure.

FIG. 6 illustrates an exemplary process for obtaining a contour of a mask feature based on the two-dimensional elements, according to an embodiment of the present disclosure.

FIG. 7 illustrates an exemplary mask feature contour made with two-dimensional elements that honor MRC rules and an exemplary contour made with two-dimensional elements that allow flexibility with MRC rules, according to various embodiments of the present disclosure.

FIG. 8A illustrates exemplary clusters of two-dimensional elements arranged on tip-to-tip and separated based on MRC rules, according to an embodiment of the present disclosure.

FIG. 8B illustrates exemplary clusters of two-dimensional elements arranged on tip-to-side and separated based on MRC rules, according to an embodiment of the present disclosure.

FIG. 9 illustrates an exemplary merging of clusters of two-dimensional elements based on MRC rules, according to an embodiment of the present disclosure.

FIG. 10A illustrates replicating clusters of two-dimensional elements in symmetric locations on a mask pattern to ensure OPC pattern consistency, according to an embodiment of the present disclosure.

FIG. 10B illustrates adjusting corresponding two-dimensional elements in the consistent clusters, according to an embodiment of the present disclosure.

FIG. 11A illustrates priority two-dimensional elements near a mask boundary, according to an embodiment of the present disclosure.

FIG. 11B illustrates priority two-dimensional elements near a mask boundary being excluded from an adjustment, according to an embodiment of the present disclosure.

FIG. 12 is a process flow diagram illustrating an exemplary method of utilizing priority two-dimensional shapes to improve mask consistency near a mask boundary, according to an embodiment of the present disclosure.

FIG. 13 is a block diagram of an example computer system, according to an embodiment of the present disclosure.

FIG. 14 is a schematic diagram of a lithographic projection apparatus, according to an embodiment of the present disclosure.

FIG. 15 is a schematic diagram of another lithographic projection apparatus, according to an embodiment of the present disclosure.

FIG. 16 is a detailed view of the lithographic projection apparatus, according to an embodiment of the present disclosure.

FIG. 17 is a detailed view of the source collector module of the lithographic projection apparatus, according to an embodiment of the present disclosure.

### DETAILED DESCRIPTION

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” are used to encompass all types of electromagnetic radiation, including ultraviolet radiation (e.g., with a wavelength of 365, 248, 193, 157 or 126 nm) and EUV (extreme ultra-violet radiation, e.g., having a wavelength in the range of about 5-100 nm).

The patterning device can comprise, or can form, one or more design layouts. The design layout can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between devices (such as gates, capacitors, etc.) or interconnect lines, so as to ensure that the devices or lines do not interact with one another in an undesirable way. One or more of the design rule limitations may be referred to as “critical dimension” (CD). A critical dimension of a device can be defined as the smallest width of a line or hole or the smallest space between two lines or two holes. Thus, the CD determines the overall size and density of the designed device. Of course, one of the goals in device fabrication is to faithfully reproduce the original design intent on the substrate (via the patterning device).

The term “mask” or “patterning device” as employed in this text may be broadly interpreted as referring to a generic patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include a programmable mirror array and a programmable LCD array.

An example of a programmable mirror array can be a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic methods.

An example of a programmable LCD array is given in U.S. Pat. No. 5,229,872, which is incorporated herein by reference.

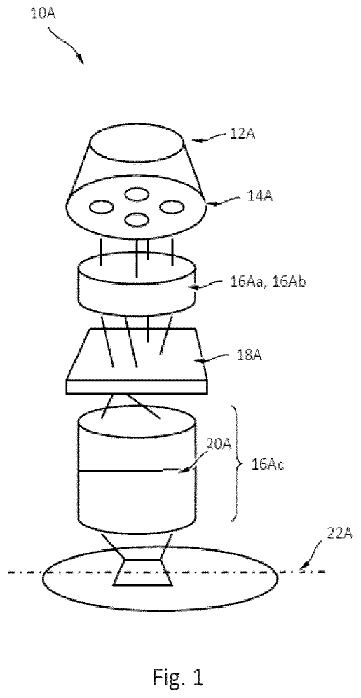

FIG. 1 illustrates a block diagram of various subsystems of a lithographic projection apparatus 10A, according to an embodiment. Major components are a radiation source 12A, which may be a deep-ultraviolet excimer laser source or other type of source including an extreme ultraviolet (EUV) source (as discussed above, the lithographic projection apparatus itself need not have the radiation source), illumination optics which, e.g., define the partial coherence (denoted as sigma) and which may include optics 14A, 16Aa and 16Ab that shape radiation from the source 12A; a patterning device 18A; and transmission optics 16Ac that project an image of the patterning device pattern onto a substrate plane 22A. An adjustable filter or aperture 20A at the pupil plane of the projection optics may restrict the range of beam angles that impinge on the substrate plane 22A, where the largest possible angle defines the numerical aperture of the projection optics NA=n sin(Θₘₐₓ), wherein n is the refractive index of the media between the substrate and the last element of the projection optics, and Θₘₐₓ is the largest angle of the beam exiting from the projection optics that can still impinge on the substrate plane 22A.

In a lithographic projection apparatus, a source provides illumination (i.e. radiation) to a patterning device and projection optics direct and shape the illumination, via the patterning device, onto a substrate. The projection optics may include at least some of the components 14A, 16Aa, 16Ab and 16Ac. An aerial image (AI) is the radiation intensity distribution at substrate level. A resist model can be used to calculate the resist image from the aerial image, an example of which can be found in U.S. Patent Application Publication No. US 2009-0157630, the disclosure of which is hereby incorporated by reference in its entirety. The resist model is related only to properties of the resist layer (e.g., effects of chemical processes which occur during exposure, post-exposure bake (PEB) and development). Optical properties of the lithographic projection apparatus (e.g., properties of the illumination, the patterning device and the projection optics) dictate the aerial image and can be defined in an optical model. Since the patterning device used in the lithographic projection apparatus can be changed, it is desirable to separate the optical properties of the patterning device from the optical properties of the rest of the lithographic projection apparatus including at least the source and the projection optics. Details of techniques and models used to transform a design layout into various lithographic images (e.g., an aerial image, a resist image, etc.), apply OPC using those techniques and models and evaluate performance (e.g., in terms of process window) are described in U.S. Patent Application Publication Nos. US 2008-0301620, 2007-0050749, 2007-0031745, 2008-0309897, 2010-0162197, and 2010-0180251, the disclosure of each which is hereby incorporated by reference in its entirety.

One aspect of understanding a lithographic process is understanding the interaction of the radiation and the patterning device. The electromagnetic field of the radiation after the radiation passes the patterning device may be determined from the electromagnetic field of the radiation before the radiation reaches the patterning device and a function that characterizes the interaction. This function may be referred to as the mask transmission function (which can be used to describe the interaction by a transmissive patterning device and/or a reflective patterning device).

The mask transmission function may have a variety of different forms. One form is binary. A binary mask transmission function has either of two values (e.g., zero and a positive constant) at any given location on the patterning device. A mask transmission function in the binary form may be referred to as a binary mask. Another form is continuous. Namely, the modulus of the transmittance (or reflectance) of the patterning device is a continuous function of the location on the patterning device. The phase of the transmittance (or reflectance) may also be a continuous function of the location on the patterning device. A mask transmission function in the continuous form may be referred to as a continuous tone mask or a continuous transmission mask (CTM). For example, the CTM may be represented as a pixelated image, where each pixel may be assigned a value between 0 and 1 (e.g., 0.1, 0.2, 0.3, etc.) instead of binary value of either 0 or 1. In an embodiment, CTM may be a pixelated gray scale image, where each pixel having values (e.g., within a range [−255, 255], normalized values within a range [0, 1] or [−1, 1] or other appropriate ranges).

The thin-mask approximation, also called the Kirchhoff boundary condition, is widely used to simplify the determination of the interaction of the radiation and the patterning device. The thin-mask approximation assumes that the thickness of the structures on the patterning device is very small compared with the wavelength and that the widths of the structures on the mask are very large compared with the wavelength. Therefore, the thin-mask approximation assumes the electromagnetic field after the patterning device is the multiplication of the incident electromagnetic field with the mask transmission function. However, as lithographic processes use radiation of shorter and shorter wavelengths, and the structures on the patterning device become smaller and smaller, the assumption of the thin-mask approximation can break down. For example, interaction of the radiation with the structures (e.g., edges between the top surface and a sidewall) because of their finite thicknesses (“mask 3D effect” or “M3D”) may become significant. Encompassing this scattering in the mask transmission function may enable the mask transmission function to better capture the interaction of the radiation with the patterning device. A mask transmission function under the thin-mask approximation may be referred to as a thin-mask transmission function. A mask transmission function encompassing M3D may be referred to as a M3D mask transmission function.

According to an embodiment of the present disclosure, one or more images may be generated. The images includes various types of signal that may be characterized by pixel values or intensity values of each pixel. Depending on the relative values of the pixel within the image, the signal may be referred as, for example, a weak signal or a strong signal, as may be understood by a person of ordinary skill in the art. The term “strong” and “weak” are relative terms based on intensity values of pixels within an image and specific values of intensity may not limit scope of the present disclosure. In an embodiment, the strong and weak signal may be identified based on a selected threshold value. In an embodiment, the threshold value may be fixed (e.g., a midpoint of a highest intensity and a lowest intensity of pixel within the image. In an embodiment, a strong signal may refer to a signal with values greater than or equal to an average signal value across the image and a weak signal may refer to signal with values less than the average signal value. In an embodiment, the relative intensity value may be based on percentage. For example, the weak signal may be signal having intensity less than 50% of the highest intensity of the pixel (e.g., pixels corresponding to a design layout may be considered pixels with highest intensity) within the image. Furthermore, each pixel within an image may considered as a variable. According to the present embodiment, derivatives or partial derivative may be determined with respect to each pixel within the image and the values of each pixel may be determined or modified according to a cost function based evaluation and/or gradient based computation of the cost function. For example, a CTM image may include pixels, where each pixel is a variable that can take any real value.

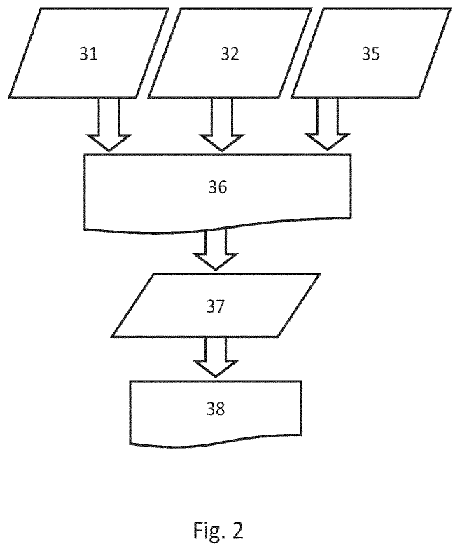

FIG. 2 illustrates an exemplary flow chart for simulating lithography in a lithographic projection apparatus, according to an embodiment. Source model 31 represents optical characteristics (including radiation intensity distribution and/or phase distribution) of the source. Projection optics model 32 represents optical characteristics (including changes to the radiation intensity distribution and/or the phase distribution caused by the projection optics) of the projection optics. Design layout model 35 represents optical characteristics of a design layout (including changes to the radiation intensity distribution and/or the phase distribution caused by design layout 33), which is the representation of an arrangement of features on or formed by a patterning device. Aerial image 36 can be simulated from design layout model 35, projection optics model 32, and design layout model 35. Resist image 38 can be simulated from aerial image 36 using resist model 37. Simulation of lithography can, for example, predict contours and CDs in the resist image.

More specifically, it is noted that source model 31 can represent the optical characteristics of the source that include, but not limited to, numerical aperture settings, illumination sigma (o) settings as well as any particular illumination shape (e.g., off-axis radiation sources such as annular, quadrupole, dipole, etc.). Projection optics model 32 can represent the optical characteristics of the projection optics, including aberration, distortion, one or more refractive indexes, one or more physical sizes, one or more physical dimensions, etc. Design layout model 35 can represent one or more physical properties of a physical patterning device, as described, for example, in U.S. Pat. No. 7,587,704, which is incorporated by reference in its entirety. The objective of the simulation is to accurately predict, for example, edge placement, aerial image intensity slope and/or CD, which can then be compared against an intended design. The intended design is generally defined as a pre-OPC design layout which can be provided in a standardized digital file format such as GDSII or OASIS or other file format.

From this design layout, one or more portions may be identified, which are referred to as “clips”. In an embodiment, a set of clips is extracted, which represents the complicated patterns in the design layout (typically about 50 to 1000 clips, although any number of clips may be used). These patterns or clips represent small portions (i.e. circuits, cells or patterns) of the design and more specifically, the clips typically represent small portions for which particular attention and/or verification is needed. In other words, clips may be the portions of the design layout, or may be similar or have a similar behavior of portions of the design layout, where one or more critical features are identified either by experience (including clips provided by a customer), by trial and error, or by running a full-chip simulation. Clips may contain one or more test patterns or gauge patterns.

An initial larger set of clips may be provided a priori by a customer based on one or more known critical feature areas in a design layout which require particular image optimization. Alternatively, in another embodiment, an initial larger set of clips may be extracted from the entire design layout by using some kind of automated (such as machine vision) or manual algorithm that identifies the one or more critical feature areas.

In a lithographic projection apparatus, as an example, a cost function may be expressed as

$$CF ( {z}_{1} , {z}_{2} , … , {z}_{N} ) = {\sum }_{p = 1}^{P} {w}_{p} {f}_{p}^{2} ( {z}_{1} , {z}_{2} , … , {z}_{N} ) \qquad ( Eq . 1 )$$

where (z₁, z₂, . . . , z_{N}) are N design variables or values thereof. fₚ(z₁, z₂, . . . , z_{N}) can be a function of the design variables (z₁, z₂, . . . , z_{N}) such as a difference between an actual value and an intended value of a characteristic for a set of values of the design variables of (z₁, z₂, . . . , z_{N}). wₚ is a weight constant associated with fₚ(z₁, z₂, . . . , z_{N}). For example, the characteristic may be a position of an edge of a pattern, measured at a given point on the edge. Different fₚ(z₁, z₂, . . . , z_{N}) may have different weight wₚ. For example, if a particular edge has a narrow range of permitted positions, the weight wₚ for the fₚ(z₁, z₂, . . . , z_{N}) representing the difference between the actual position and the intended position of the edge may be given a higher value. fₚ(z₁, z₂, . . . , z_{N}) can also be a function of an interlayer characteristic, which is in turn a function of the design variables (z₁, z₂, . . . , z_{N}). Of course, CF(z₁, z₂, . . . , z_{N}) is not limited to the form in Eq. 1. CF(z₁, z₂, . . . , z_{N}) can be in any other suitable form.

The cost function may represent any one or more suitable characteristics of the lithographic projection apparatus, lithographic process or the substrate, for instance, focus, CD, image shift, image distortion, image rotation, stochastic variation, throughput, local CD variation, process window, an interlayer characteristic, or a combination thereof. In one embodiment, the design variables (z₁, z₂, . . . , z_{N}) comprise one or more selected from dose, global bias of the patterning device, and/or shape of illumination. Since it is the resist image that often dictates the pattern on a substrate, the cost function may include a function that represents one or more characteristics of the resist image. For example, fₚ(z₁, z₂, . . . , z_{N}) can be simply a distance between a point in the resist image to an intended position of that point (i.e., edge placement error EPEₚ(z₁, z₂, . . . , z_{N}). The design variables can include any adjustable parameter such as an adjustable parameter of the source, the patterning device, the projection optics, dose, focus, etc.

The lithographic apparatus may include components collectively called a “wavefront manipulator” that can be used to adjust the shape of a wavefront and intensity distribution and/or phase shift of a radiation beam. In an embodiment, the lithographic apparatus can adjust a wavefront and intensity distribution at any location along an optical path of the lithographic projection apparatus, such as before the patterning device, near a pupil plane, near an image plane, and/or near a focal plane. The wavefront manipulator can be used to correct or compensate for certain distortions of the wavefront and intensity distribution and/or phase shift caused by, for example, the source, the patterning device, temperature variation in the lithographic projection apparatus, thermal expansion of components of the lithographic projection apparatus, etc. Adjusting the wavefront and intensity distribution and/or phase shift can change values of the characteristics represented by the cost function. Such changes can be simulated from a model or actually measured. The design variables can include parameters of the wavefront manipulator.

The design variables may have constraints, which can be expressed as (z₁, z₂, . . . , z_{N})ϵZ, where Z is a set of possible values of the design variables. One possible constraint on the design variables may be imposed by a desired throughput of the lithographic projection apparatus. Without such a constraint imposed by the desired throughput, the optimization may yield a set of values of the design variables that are unrealistic. For example, if the dose is a design variable, without such a constraint, the optimization may yield a dose value that makes the throughput economically impossible. However, the usefulness of constraints should not be interpreted as a necessity. For example, the throughput may be affected by the pupil fill ratio. For some illumination designs, a low pupil fill ratio may discard radiation, leading to lower throughput. Throughput may also be affected by the resist chemistry. Slower resist (e.g., a resist that requires higher amount of radiation to be properly exposed) leads to lower throughput.

As used herein, the term “patterning process” means a process that creates an etched substrate by the application of specified patterns of light as part of a lithography process.

As used herein, the term “design layout” means an idealized pattern that is to be formed on a substrate.

As used herein, the term “printed pattern” means the physical pattern on a substrate that was formed based on a design layout. The printed pattern can include, for example, vias, contact holes, troughs, channels, depressions, edges, or other two and three dimensional features resulting from a lithography process.

As used herein, the term “process model” means a model that includes one or more models that simulate a patterning process. For example, a process model can include any combination of: an optical model (e.g., that models a lens system/projection system used to deliver light in a lithography process and may include modelling the final optical image of light that goes onto a photoresist), a mask model, a resist model (e.g., that models physical effects of the resist, such as chemical effects due to the light), an OPC model (e.g., that can be used to make design layouts and may include sub-resolution resist features (SRAFs), etc.), an imaging device model (e.g., that models what an imaging device may image from a printed pattern).

As used herein, the term “imaging device” means any number or combination of devices and associated computer hardware and software that can be configured to generate images of a target, such as the printed pattern or portions thereof. Non-limiting examples of an imaging devices can include: scanning electron microscopes (SEMs), x-ray machines, etc.

As used herein, the term “calibrating” means to modify (e.g., improve or tune) and/or validate, such as the process model.

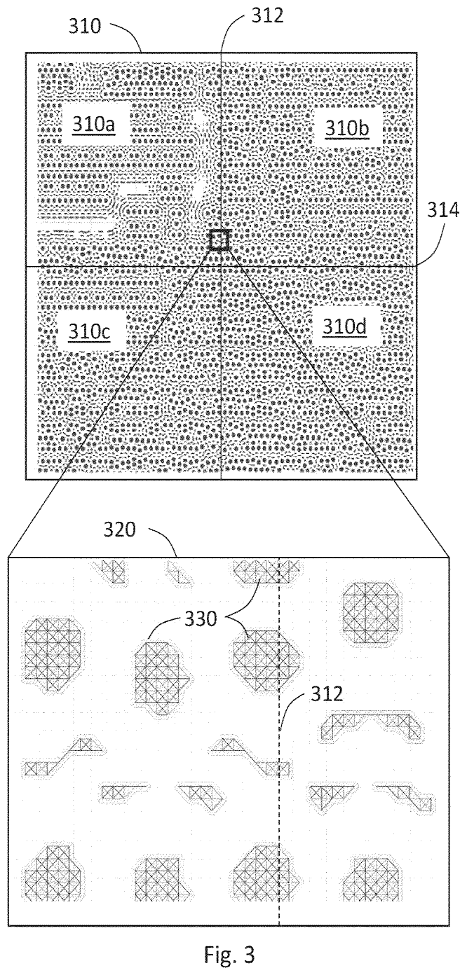

FIG. 3 illustrates an exemplary mask pattern and mask features. Mask pattern 310 in FIG. 3 shows a complex pattern of mask features such as vias, troughs, channels, etc. In some embodiments, a mask pattern can be divided into sections, referred to herein as mask patches. Mask pattern 310 is depicted with four mask patches 310a, 310b, 310c, and 310d, though any number or arrangement of mask patches is possible. The mask patches can be separated by boundaries, for example, boundary 312 and boundary 314. An expanded portion of mask pattern 310 is shown as inset 320. At this scale, the shapes of mask features 330 are clearly visible. As shown in the inset, some mask features 330 can extend across boundary 312.

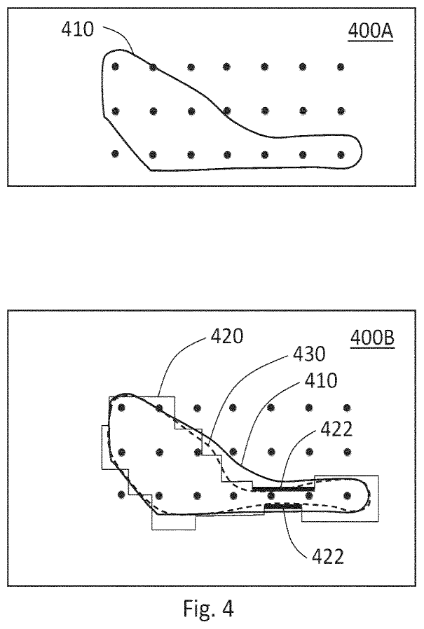

FIG. 4 illustrates a mask feature generated with conventional OPC violating MRC rules. OPC can be utilized in mask design to optimize the mask so that the mask ultimately delivers light to a substrate such that the desired design layout is formed. One example of a mask feature 410 (e.g., what could be on a fully optimized mask) is depicted in the top portion 400A of FIG. 4, with an exemplary grid shown by the dots for reference. The example mask feature 410 has some portions that are curvilinear shape and can be optimized through simulation to result in the desired feature on the printed pattern. Conventional mask optimization can include starting from target pattern polygons (e.g., representing a desired pattern to be fabricated) and extracting such polygons to serve as the basis of a mask. Then, points or line segments representing mask feature boundaries (or for a CTM, pixel values in the mask pattern that represent transmission) are iteratively adjusted until an optimized mask pattern is obtained that would result in the closest printed pattern (e.g., as simulated such as with SMO or other process simulators). However, such conventional optimization of mask features can be computationally expensive as there can be many elements that need to be adjusted in order to form the optimized mask feature. In the bottom portion 400B of FIG. 4, a rectilinear mask feature 420 can be utilized to approximate an arbitrary shape of a mask feature (e.g., mask feature 410) and can also be optimized with conventional OPC but in a simpler manner than curvilinear mask features due to having to only adjust line segments instead of points on a continuous curve.

Optimization resulting from conventional OPC can sometimes result in mask features that violate Mask Rule Checks (MRC) rules. As one example, an MRC rule can require that a mask feature have a certain minimum width to avoid impermissibly small features that cannot possibly be constructed or may have a high likelihood of errors in manufacturing. As shown in the example in FIG. 4, the optimized rectilinear mask feature 420 has a portion 422 (shown with the heavier lines) that is significantly narrower than the corresponding location in the mask feature 410. In this example, the optimization was not constrained to obey the MRC rules and thus produced a mask feature 430 (e.g., a mask feature that would result on a physical mask, if constructed) with a similarly narrow portion that may not be suitable for actual mask production.

The present disclosure provides embodiments which, for example, provide efficient methods of constructing and optimizing mask features such that MRC rules can be more easily (and in some embodiments even automatically) obeyed, facilitate optimization by consistent modification of like mask features, and improve consistency of geometry of mask features across boundaries between mask patches.

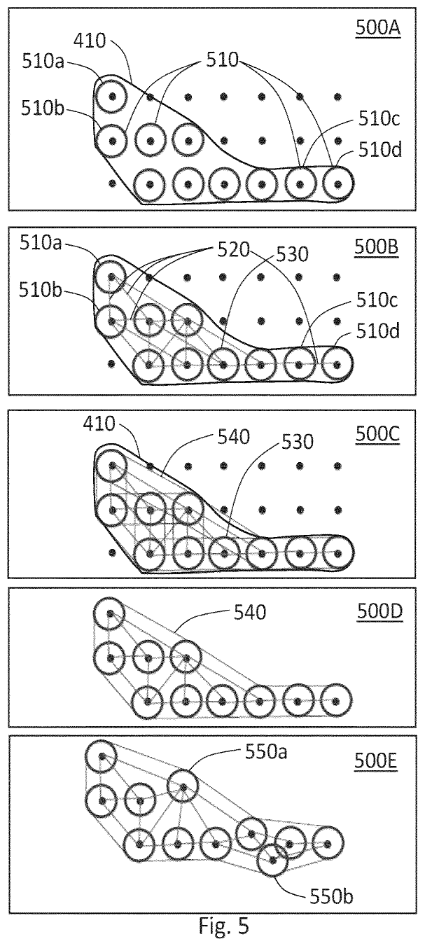

According to embodiments of the present disclosure, in the OPC process, mask feature representations are constructed by using arrays of two-dimensional elements that are defined based on MRC rules. FIG. 5 illustrates an exemplary process for placing, associating, and adjusting two-dimensional elements forming a mask feature, according to an embodiment of the present disclosure. In some embodiments, determining a mask pattern (or portions thereof) for use with a lithographic process can include assigning locations of two-dimensional elements 510 based on a target pattern. As shown in the first (top) portion 500A of FIG. 5, in contrast to the rectilinear segments in conventional OPC (as shown in FIG. 4), the shape of the mask feature 410 can be represented by a collection of two-dimensional elements 510 (in this example shown as circles). Four of the two-dimensional elements are labeled as 510a-d. Though described further herein, it can be seen that a contour formed around the two-dimensional elements (e.g., the circles having a diameter of at least a minimum width as specified by an MRC rule) can inherently and automatically satisfy the MRC rule regardless of the locations of the two-dimensional elements.

The next panel 500B in FIG. 5 depicts an example of associating the two-dimensional elements based on association criteria to form a cluster 530 that represents a mask feature. The associations 520 are depicted as line segments between the two-dimensional elements. The two-dimensional elements that are associated can then be utilized, as explained further herein, to form cluster 530 that has a shape corresponding to mask feature 410. In FIG. 5, all of the two-dimensional elements shown are part of the exemplary cluster. Not all two-dimensional elements in a cluster need be associated to each other as the elements that are associated are dependent on the mask feature optimization. For example, two-dimensional element 510a in the upper left is not associated with two-dimensional element 510d on the lower right, though through their associations with other two-dimensional elements are part of the same cluster 530.

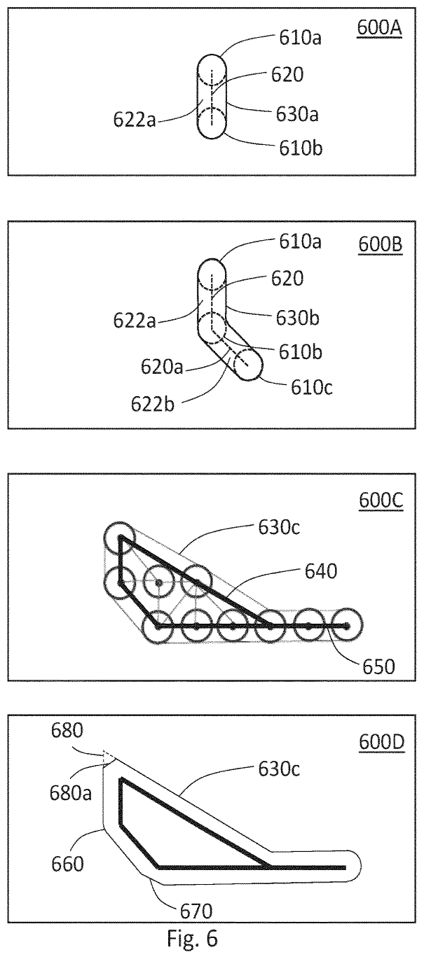

The middle panel 500C in FIG. 5 depicts an exemplary contour 540 around the cluster 530. As described in further detail herein, such as with reference to FIG. 6, contour 540 can be generated to encompass an area formed by the two-dimensional elements and a region between the two-dimensional elements. Accordingly, the contour can be an outer contour of a cluster that corresponds to an outer edge of a mask feature. Similarly, for mask features having an inner edge such as a donut-shaped mask feature, the contour can be an inner contour of the cluster that corresponds to an inner edge of the mask feature.

The next panel 500D is similar to the middle panel, again showing two-dimensional elements 510, associations 520, cluster 530, and contour 540, but without showing the lines forming the regions between two-dimensional elements or showing the mask feature 410. Here, contour 540 is more clearly visible and surrounding the cluster of two-dimensional elements.

The bottom panel 500E in FIG. 5 depicts adjusting the two-dimensional elements of the cluster to vary the mask feature formed by the cluster. In some embodiments, the adjusting of mask features can be based on a simulation associated with the lithography process, OPC models, etc. In other embodiments, the adjusting of mask features can be based on geometric properties of the mask pattern (e.g., widths, separations, etc.) and based on rules prescribed for OPC (e.g., adding serifs, bias, hammerhead, SRAFs, etc. on the main features). In some embodiments where adjustments are based on simulations, a mask generation process, as in SMO or OPC, etc. can optimize mask features by adjusting any combination of the two-dimensional elements of any of the clusters formed for the simulated mask. In this example, two-dimensional element 550a is shown at a slightly different position and two-dimensional element 550b has been added (with nearby two-dimensional elements also moved slightly). As used herein, “adjusting” a two-dimensional element means to move, change the shape of, or add/subtract a two-dimensional element. For example, the centers of the circular two-dimensional elements can be moved as needed to optimize the mask. In other implementations, the radius of the circular two-dimensional elements can be changed as part of the optimization process. With such methods of determining/adjusting the contours of mask features, any of the disclosed methods can include manufacturing a mask from a mask pattern that includes contours generated from adjusted two-dimensional elements.

The present disclosure contemplates that many kinds of two-dimensional elements can be utilized. As the two-dimensional elements can be utilized to define at least a particular dimension (e.g., a CD, minimum spacing between mask features, etc.), and in some cases a particular area (e.g., a minimum area allowed for a mask feature), the two-dimensional elements can define a non-zero area (e.g., as distinct from a point). For example, the two-dimensional elements can be circular, or more generally, elliptical. The two-dimensional elements can be the same size or can vary in size within a cluster or among clusters. It is not necessary that the two-dimensional elements are circular/elliptical. For example, the two-dimensional elements can be a polygon (e.g., square, triangle, rectangle, hexagon, etc.) or a suitable arbitrary shape. In such implementations, the contour can be inscribed around the vertices or inscribed against the edges. Such two-dimensional elements can define an enclosed or semi-enclosed area (e.g., the area of the circles, as shown). While shapes such as circles, polygons, etc. are examples of enclosed areas, in some embodiments a two-dimensional element can be effectively represented by an arc or other similar structure. For example, the same contour in the bottom panel of FIG. 5 could be generated by positioning arc segments having the same centers as the circles and with the arc segments appropriately oriented and having sufficient length to produce the depicted contour. Accordingly, substantial equivalents to the exemplary two-dimensional elements depicted herein are considered within the scope of the present disclosure.

The present disclosure is not limited to any specific mechanism of determining contours from a cluster of two-dimensional elements. For example, FIG. 6 illustrates an exemplary process for obtaining a contour of a mask feature based on the two-dimensional elements, according to an embodiment of the present disclosure. The cluster of two-dimensional elements can be contoured in any suitable ways without departing from the scope of the present disclosure, with one implementation depicted in FIG. 6. The top portion 600A of FIG. 6 depicts two exemplary associated two-dimensional elements 610a and 610b. A virtual line segment 620 can connect the centers of the two-dimensional elements. It is not necessary that the system generates the virtual line segment 620, provided here for explanatory purposes. To the contour around the two-dimension elements, the virtual line segment 620 can be offset on either side by a distance equal to the radius of the two-dimensional elements. This can then form what are referred to herein as “sub-areas” (the areas of the two-dimensional elements and the area between them based on the offset lines) with one shown as sub-area 622a. In implementations where the two-dimensional elements are not the same size, the offsetting can be such that the offset distance transitions from one radius to the other. However, it will be appreciated that this discussion is merely exemplary. The offset distance or a sub-area can be defined in any other suitable manner and a mask feature may have many such sub-areas. The area enclosed by the contour can be the area occupied by the sub-areas and any corresponding areas interior to a connected collection of sub-areas (e.g., the area of the sub-areas around the perimeter of a mask feature and the area such a perimeter might enclose).

The next portion 600B of FIG. 6 extends the above example to include two-dimensional element 610c. Another virtual line segment 620a is shown between 610b and 610c as well as the corresponding offset line segments that form part of contour 630b. Accordingly, in various implementations, processes similar to that described above can include generating sub-areas (e.g., 622a and 622b) of the contour by applying a polygon offsetting operation to pairs (e.g., 610a/b and 610b/c) of the associated two-dimensional elements. The process can then include computing the union of the sub-areas, wherein the contour 630b defines the union of the sub-areas. As the depicted two-dimensional elements can form a cluster, the system can thereby generate a contour of the cluster based on the two-dimensional elements. In this example, the contour corresponds to the outer contour of all the sub-areas in the cluster that form the perimeter of the cluster. This process can be extended to an arbitrary number and configuration of two-dimensional elements as shown by the bottom portion 600C of FIG. 6, showing contour 630c as it was also depicted by contour 540 in FIG. 5.

While the example of FIG. 6 in panels 610A-C were provided to provide an exemplary step-by-step method of contouring, in some implementations the contouring can be performed with substantially fewer steps. For example, once two-dimensional elements are determined that will form the basis of a mask shape, such two-dimensional elements can then form a single shape (which may comprise any combination of polygons and line segments). This shape can then be treated as a “polygon” (again, not necessarily strictly a polygon as it may have portions that are line segments) and this “polygon” can then be contoured by performing a polygon offsetting operation, according to any of the examples herein, with a few described below.

In some embodiments, a “polygon offsetting” operation can be performed where a polygon to be contoured can be defined by selecting locations of two-dimensional elements (e.g., centers) that correspond to a desired mask feature. One example of such a polygon 640 is shown in 600C by the heavier lines, where various line segments connecting certain centers of two-dimensional elements are shown. Polygon 640 (including exemplary additional line segment 650) can then be offset (e.g., by the radius of the two-dimensional elements) to form the depicted contour 630c. Though not shown in the example of FIG. 6, any inner regions (e.g., as in a “donut-shaped” mask feature) can be similarly defined, contoured, and shaped as described herein.

The defined outer contour can be further processed in any suitable technique. As seen from the examples of circular two-dimensional elements in FIG. 5 and FIG. 6, some portions of the determined contours are naturally rounded based on the radius of the two-dimensional elements. However, in some locations such as the concave portions of the contour 630, the disclosed methods can also include performing corner rounding or any other type of smoothing operations on the outer contour. One method of corner rounding can include performing spline interpolation between two points on either side of a corner. In some embodiments, the spline interpolation can modify the contour to be smooth but may bring it out from touching a two-dimensional element. Such deviations can be acceptable as they may further reinforce compliance with a minimum width MRC rule.

In some embodiments, shown in panel 600D, rather than a rounded corner 660, the system can generate a “squared corner” 670 around a vertex of a contoured polygon such that the intersecting segments that would ordinarily make a sharp vertex are instead met with a third line segment (e.g., similar to a chamfer). Another option can be allowing the line segments to meet to form a “mitered corner” 680, however in certain embodiments this may cause an undesirable extension of the contour (e.g., which may be past a prescribed limit of distance from the associated vertex). In such cases, the system can square the mitered corner 680 to become another squared corner 680a such that the contour does not extend beyond the prescribed limit.

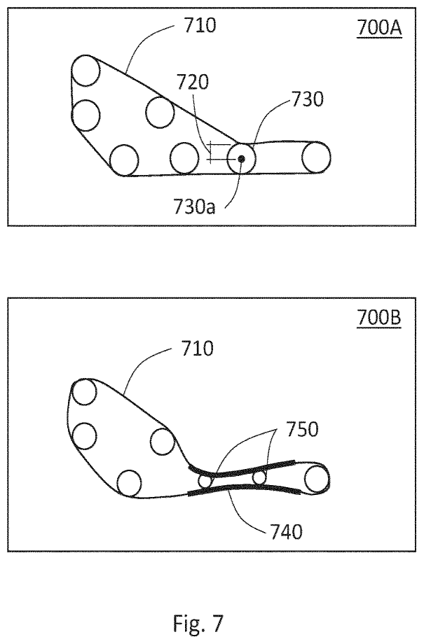

FIG. 7 illustrates an exemplary mask feature contour made with two-dimensional elements that honor MRC rules and an exemplary contour made with two-dimensional elements allow flexibility with MRC rules, according to various embodiments. In some embodiments, as shown in FIG. 7, because the contour can be at least partially a prescribed distance from the locations (e.g., centers) of the two-dimensional elements, the mask feature can naturally satisfy a minimal width requirement. The upper portion 700A of FIG. 7 depicts an embodiment where the contour (e.g., contour 710) is entirely at least the prescribed distance (e.g., prescribed distance 720) from the locations (e.g., center 730a) of the two-dimensional elements (e.g., two-dimensional element 730). While the prescribed distance can be arbitrarily set by user or otherwise manipulated by the system, in some embodiments, the prescribed distance can be based on an MRC rule for a minimum width of the mask feature. The two-dimensional elements, particularly circular two-dimensional elements, can also satisfy other MRC rules such as a minimum curvature (e.g., by having a minimum radius for the two-dimensional elements), etc.

In other embodiments, such as to allow more flexibility in calculating an optimized or converged solution for a mask, at least a portion 740 of contour 710 can be allowed to violate an MRC rule. For example, as shown in the lower portion of FIG. 7, while most of the mask feature is shown as complying with the MRC rules, there is one portion 740 (shown in heavier line) that may violate an MRC minimum width rule. This may occur, for example, where two-dimensional elements 750 have different sizes than the other two-dimensional elements, which is an option that can be implemented in some embodiments. Such flexibility can be beneficial, for example, by allowing some violation of MRC rules in particular portions of a mask design if such violations improve the overall convergence of the mask or permit compliance in more critical locations of the mask.

The geometry of the two-dimensional elements can be defined based on one or more MRC rules. For example, a dimension parameter (e.g., a diameter, distance to a polygon vertex or face, etc.) of the two-dimensional element can be selected to be a minimum width specified by the MRC rules. One technical benefit of the present disclosure is that by having some or all of the mask features formed by contouring around two-dimensional elements that are at least the size of a minimum permissible value, any optimized mask feature automatically complies with such an MRC rule. This capability affords mask simulators/optimizers to determine a mask pattern that can be efficiently optimized (e.g., by moving the two-dimensional elements as needed). The automatic compliance with such MRC rules thus causes the resultant masks to be simulated more quickly and manufactured with reduced errors.

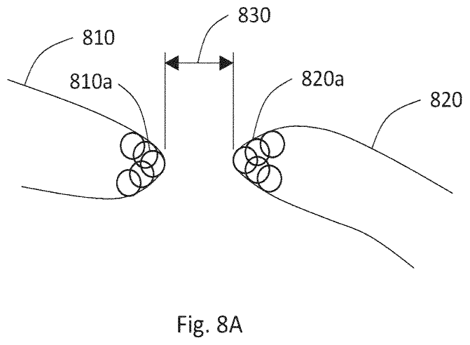

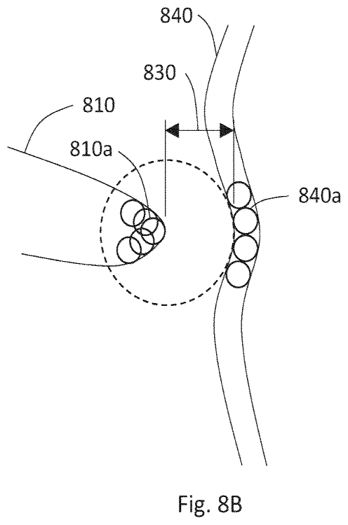

FIG. 8A illustrates exemplary clusters of two-dimensional elements arranged on tip-to-tip and separated based on MRC rules, according to an embodiment. FIG. 8B illustrates exemplary clusters of two-dimensional elements arranged on tip-to-side and separated based on MRC rules, according to an embodiment.

The MRC rules can include a minimum space requirement. For example, in FIG. 8A, contour 810 can have a cluster 810a of two-dimensional elements (only a few of which are shown in the figure). Similarly, second contour 820 can have a second cluster 820a of two-dimensional elements. As shown by the example of FIG. 8A, if the tips of two contours 810 and 820 were closer than a minimum space requirement 830, then the mask features formed from such contours may be at substantial risk of merging when the mask is constructed. A similar example is shown in FIG. 8B, where tip of contour 810 is close to the side of contour 840. According to embodiments of the present disclosure, should a two-dimensional element of either cluster violate the minimum space requirement, the two clusters (e.g., clusters 810a and 840a) and the resulting contour can merge.

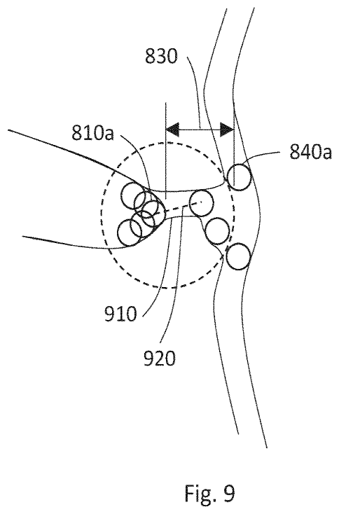

FIG. 9 illustrates an exemplary merging of clusters of two-dimensional elements based on MRC rules, according to an embodiment. To provide an MRC-compliant mask solution, some embodiments can cause contours to merge if two-dimensional elements are violating the minimum space requirement, thereby bringing the mask solution back into compliance without the need for subsequent MRC violation detection and computation procedures. Stated another way, such merging can thereby force any resultant unmerged contours to be at least the minimum distance apart-because otherwise they would have merged. As depicted by the example in FIG. 9 (based on FIG. 8B), the association criteria can include connecting (e.g., shown by association 920) a second two-dimensional element (e.g., the two-dimensional element at the tip of second cluster 820a) into the cluster (e.g., 810a) when a distance between a second contour (e.g., contour 820) for the second two-dimensional element and the contour (e.g., contour 810) for the two-dimensional elements in the cluster is less than the minimum space requirement. The same condition can be expressed in terms of distances between two-dimensional elements (e.g., the minimum space requirement can be violated by two-dimensional elements that are centered a distance of the minimum space requirement plus the sum of their respective radii).

The present disclosure provides methods that can include modifying a cluster of two-dimensional elements into one or more modified clusters. In the example of FIG. 9, adjusting of two of the two-dimensional elements caused clusters 810a and 840a to become part of the same cluster (due to being within the minimum space requirement). The resultant contour 910 reflects the modified cluster. Modifications to clusters can include, for example, adding or removing two-dimensional elements, changing the spacing between two-dimensional elements (which may cause splitting or merging of the clusters and their resultant contours), etc. Such modified clusters can be formed based on MRC rules similar to the examples given previously. In some embodiments, modifying the cluster can include modifying the cluster by dissociating (e.g., removing) one of the two-dimensional elements from the cluster and modifying the contour based on the modified cluster. In other embodiments, certain methods can include modifying the cluster by associating a two-dimensional element from another cluster with the cluster and modifying the contour based on the modified cluster, as shown in FIG. 9.

As described herein, adjustments to the two-dimensional elements can be utilized in mask optimization. For example, in the optimization process, the adjusting of the two-dimensional elements can include optimizing the mask pattern by moving a location of one or more of the two-dimensional elements, adjusting a size or a shape of one or more of the two-dimensional elements, etc. The associating of two-dimensional elements done as part of an optimization can also include associating a two-dimensional element that is within a prescribed distance from other two-dimensional elements, in other words, adding a two-dimensional element to a cluster when sufficiently close (as explained by the example of FIG. 9). Also, certain embodiments can include dissociating a two-dimensional element from the two-dimensional elements of the cluster and associating the two-dimensional element with a two-dimensional element in a second cluster. This can describe moving one two-dimensional element from one cluster to another.

As described herein, some embodiments can use cost functions to optimize a simulated pattern (e.g., for a mask, a resist layer, etc.). Cost functions, e.g., as shown in the example of Eq. 1, can include terms (e.g., z₁, z₂, etc.) such as EPE that can be minimized as part of an optimization. As the disclosed methods for mask generation (e.g., moving two-dimensional elements to optimize mask features) affect the cost calculated for a resultant mask, some embodiments can include computing a cost function that quantifies an evaluation of the mask pattern, where the adjusting of the two-dimensional elements is based on the cost function. In other words, the two-dimensional elements can be moved, resized, etc. to reduce the computed cost, and can be based on rule-based OPC or model-based OPC. In some cases, cost functions can include terms related to MRC rules, e.g., determining if MRC rules are violated and assigning a cost based on such. Because these determinations can be computationally expensive, another technical benefit of the present disclosure is that some embodiments can include cost functions that do not include any terms based on MRC rules. In these embodiments, the two-dimensional elements may automatically satisfy one or more MRC rules and therefore do not require consideration in the cost function.

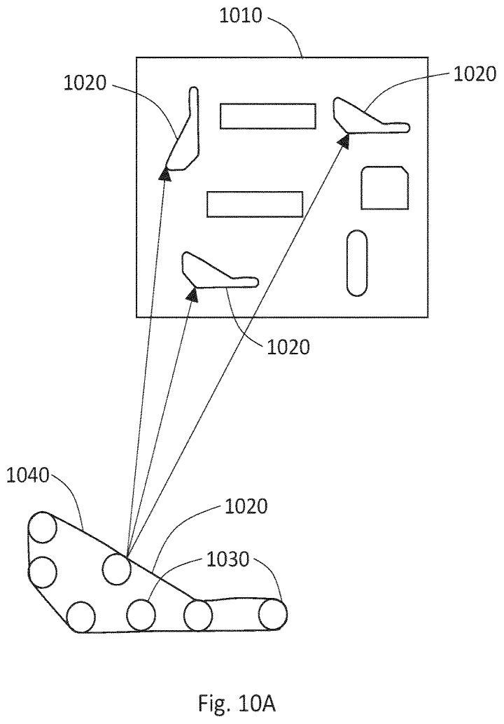

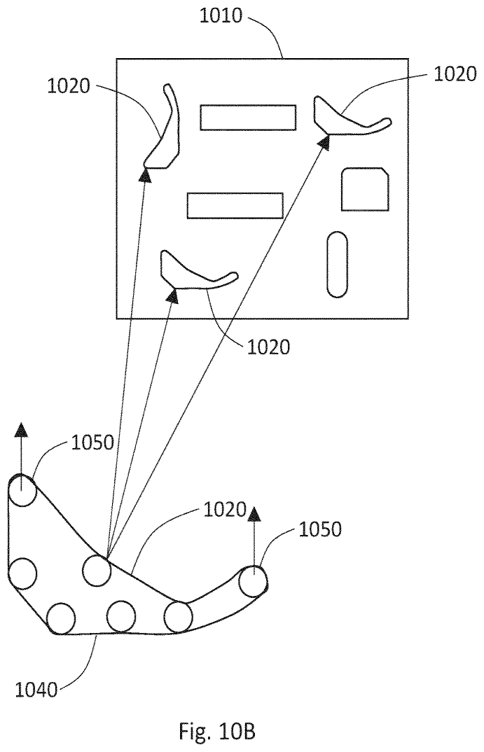

FIG. 10A illustrates replicating clusters of two-dimensional elements in symmetric locations on a mask pattern to ensure OPC pattern consistency, according to an embodiment of the present disclosure. In some cases, a pattern layout can have many features that are replicated throughout the pattern (e.g., using standard vias, troughs, etc.). Such replication of features can thereby be reflected in a mask and its respective mask features. FIG. 10A depicts an example portion 1010 of a mask having a number of mask features, with mask feature 1020 repeated in several places. Mask feature 1020 is shown in the expanded view as similar to those previously described having two-dimensional elements 1030 and contour 1040.

FIG. 10B illustrates adjusting corresponding two-dimensional elements in the consistent clusters, according to an embodiment. In some embodiments, generating “consistent clusters” (the associated two-dimensional elements in the replicated mask feature 1020) can be performed by replicating the cluster in the mask pattern, as shown in FIG. 10A. Then, such consistent clusters can be consistently adjusted by adjusting corresponding two-dimensional elements in the consistent clusters. In this example, corresponding two-dimensional elements 1050 are shown as adjusted, for example, as part of an optimization process. In the depicted example mask portion 1010, the same adjustment is made for all corresponding two-dimensional elements 1050 in the corresponding clusters in the mask pattern. In this way, the replicated consistent clusters can facilitate fast and consistent adjustments to features used throughout a mask, allowing many adjustments to be made with a single (or comparatively few) command(s).

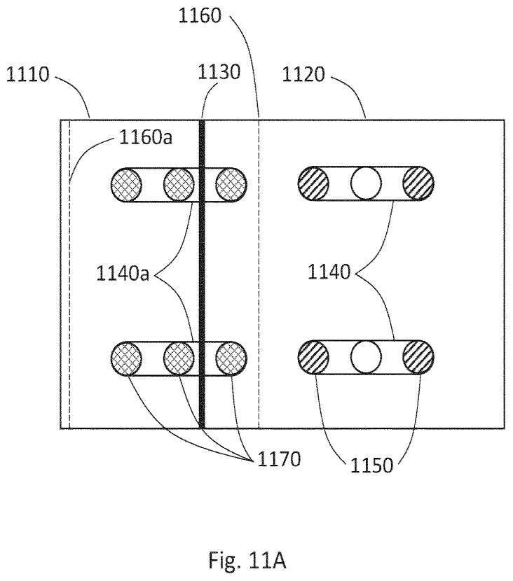

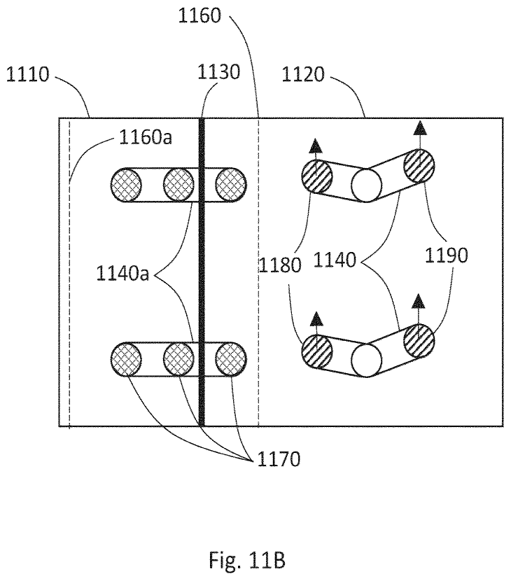

FIG. 11A illustrates priority two-dimensional elements near a mask boundary, according to an embodiment. To improve consistency of mask features across patch boundaries, some embodiments can include adjusting of the consistent clusters by identifying a boundary two-dimensional element across a boundary between a first mask patch and a second mask patch, where adjusting the two-dimensional elements can exclude adjusting the boundary two-dimensional element. In some embodiments, this can include designating certain two-dimensional elements as priority two-dimensional elements. Such elements can have priority in the sense that they may be excluded from adjustment by processes that otherwise adjust them as described herein (e.g., belonging to consistent clusters). For example, when patches are processed sequentially, a first patch can be optimized first and have a mask feature at the boundary be adjusted. To ensure consistency across the boundary, when a second patch is optimized, some or all of the two-dimensional elements in the mask feature from the first mask can be designated as “priority” in the second patch-meaning, not to be adjusted with the rest of the second patch.

The example shown in FIG. 11A depicts a first mask patch 1110 and a second mask patch 1120 separated by boundary 1130. Mask feature 1140 and 1140a are depicted as a mask feature having been replicated in four places, with two instances (1140a) going across boundary 1130 that can be handled differently than the other two instances (1140). Similar to that described with reference to FIG. 10A/B, corresponding two-dimensional elements 1150 (at the ends of mask features) are depicted with single crosshatching. The corresponding two-dimensional elements 1150 in the second mask patch 1120 can be adjusted in the manner described for similar corresponding two-dimensional elements 1050 in FIGS. 10A/B. However, the similar two-dimensional elements (at the ends of mask feature 1140a) can be handled differently. In some embodiments, to improve mask feature consistency across a boundary, two-dimensional elements that are within a threshold distance to boundary 1130 of first mask patch 1110 and second mask patch 1120 can be designated as priority two-dimensional elements 1170 and are depicted with the double crosshatching. The threshold distance can be defined by a parameter set by the system or a user with an exemplary depiction of such a region shown by the dashed lines. The threshold distance for the designation of two-dimensional elements being priority two-dimensional elements need not be the same on either side of boundary 1130. For example, as shown, second threshold distance 1160 in second patch 1120 and a corresponding first threshold distance 1160a in the first patch is depicted as further from boundary 1130 than the second threshold distance 1160, thereby encompassing all of the shown two-dimensional elements in the first patch 1110. Thus, in some embodiments, some, or all of the two-dimensional elements in mask feature(s) 1140a spanning boundary 1160 can be designated as priority two-dimensional elements 1170 and therefore the two-dimensional elements of mask feature(s) 1140a may not be adjusted with other two-dimensional elements of the second patch 1120 (e.g., two-dimensional elements 1150) even though were the boundary not located where it was, they may have been adjusted as corresponding two-dimensional elements in a manner similar to that depicted in FIG. 10A/B.

FIG. 11B illustrates priority two-dimensional elements near a mask boundary being excluded from an adjustment, according to an embodiment. FIG. 11B depicts that in some embodiments adjusting the two-dimensional elements can exclude adjusting any priority two-dimensional elements. In this way, certain applications can benefit from having more guaranteed consistency of mask features across patch boundaries even during an optimization process where two-dimensional elements may be moving, resized, etc. This can also include, for example, regrouping some two-dimensional elements near the boundary (e.g., regrouping two-dimensional elements 1170 as its own cluster, and optionally doing the same for the similar two-dimensional elements of the other mask feature 1140a). As shown in FIG. 11B and as described above, in some embodiments, the priority two-dimensional elements 1170 can comprise an entire mask feature 1140a that extends over boundary 1130. In such embodiments, the mask feature(s) 1140a extending over boundary 1130 can be adjusted as part of optimizing the first patch 1110 (on one side of the boundary), but then not adjusted when optimizing the second patch 1120, even though the mask feature(s) 1140a have some two-dimensional elements on the second patch 1120. This can further ensure that such boundary-crossing mask features are not adjusted in ways that would modify the optimization of the first patch 1110. In some embodiments, two-dimensional elements of the second patch 1120 near the patch boundary 1130 may be regrouped. For example, the two elements as 1150 in FIG. 11A may be regrouped to belong to two different groups 1180 and 1190. The two groups can be handled separately when adjusting the two-dimensional elements, for example as a result of group 1180 being closer to boundary 1130 and priority two-dimensional elements 1170 in mask feature 1140a.

In some embodiments, the priority two-dimensional elements can be stored in computer memory for later recall. For example, this can facilitate some embodiments replacing one or more of the two-dimensional elements within the threshold distance to the boundary with priority two-dimensional elements. Such two-dimensional elements can thereby both improve computational performance by not having to recalculate or be optimize the contours in boundary areas, as well as improving the consistency of such mask features across boundaries.

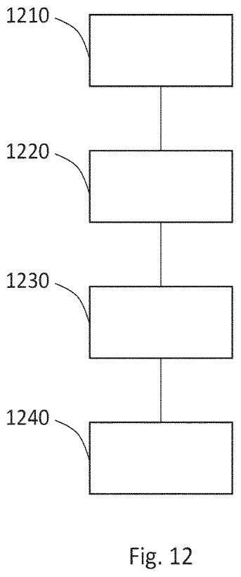

FIG. 12 is a process flow diagram illustrating an exemplary method of utilizing priority two-dimensional shapes to improve mask consistency near a mask boundary, according to an embodiment of the present disclosure.

The method can include, at 1210, receiving a mask pattern. The mask pattern can be an initial mask pattern, a partially optimized mask pattern, a mask pattern that needs re-optimization based on changes to a source, MRC rules, an updated design layout, etc.

At 1220, the method can include generating consistent clusters by replicating the cluster in the mask pattern. The adjusting can include adjusting corresponding two-dimensional elements in the consistent clusters.

At 1220, the method can include designating the two-dimensional elements that are within a threshold distance of a boundary of a first mask patch and a second mask patch as priority two-dimensional elements.

At 1230, the method can include replacing one or more of the two-dimensional elements close to the boundary with priority two-dimensional elements recalled from computer memory.

At 1240, the method can include generating an adjusted mask pattern based on the two-dimensional elements in the consistent clusters. Adjusting the two-dimensional elements can exclude adjusting any priority two-dimensional elements.

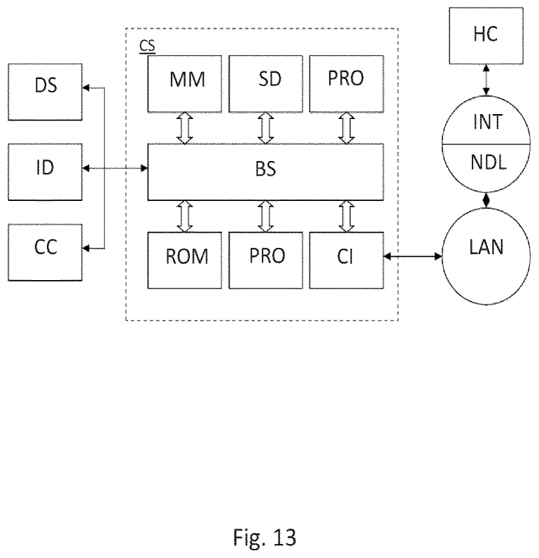

FIG. 13 is a block diagram of an example computer system CS, according to an embodiment of the present disclosure.

Computer system CS includes a bus BS or other communication mechanism for communicating information, and a processor PRO (or multiple processor) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions to be executed by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

According to one embodiment, portions of one or more methods described herein may be performed by computer system CS in response to processor PRO executing one or more sequences of one or more instructions contained in main memory MM. Such instructions may be read into main memory MM from another computer-readable medium, such as storage device SD. Execution of the sequences of instructions contained in main memory MM causes processor PRO to perform the process steps described herein. One or more processors in a multi-processing arrangement may also be employed to execute the sequences of instructions contained in main memory MM. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the features described herein. Transitory computer-readable media can include a carrier wave or other propagating electromagnetic signal.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) both use electrical, electromagnetic or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

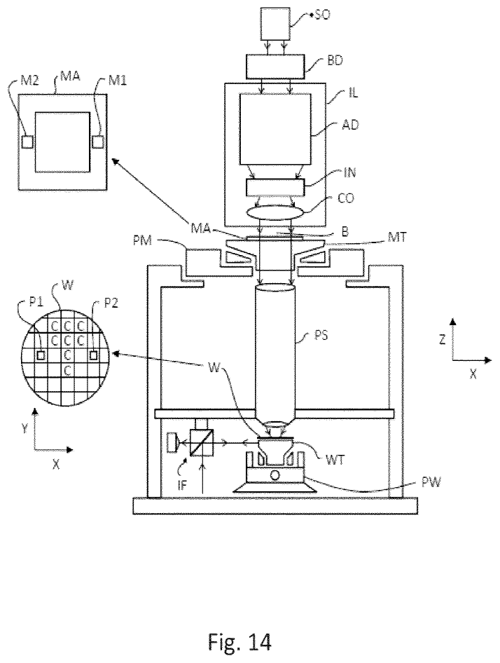

FIG. 14 is a schematic diagram of a lithographic projection apparatus, according to an embodiment of the present disclosure.

The lithographic projection apparatus can include an illumination system IL, a first object table MT, a second object table WT, and a projection system PS.

Illumination system IL, can condition a beam B of radiation. In this particular case, the illumination system also comprises a radiation source SO.

First object table (e.g., patterning device table) MT can be provided with a patterning device holder to hold a patterning device MA (e.g., a reticle), and connected to a first positioner to accurately position the patterning device with respect to item PS.

Second object table (substrate table) WT can be provided with a substrate holder to hold a substrate W (e.g., a resist-coated silicon wafer), and connected to a second positioner to accurately position the substrate with respect to item PS.

Projection system (“lens”) PS (e.g., a refractive, catoptric or catadioptric optical system) can image an irradiated portion of the patterning device MA onto a target portion C (e.g., comprising one or more dies) of the substrate W.

As depicted herein, the apparatus can be of a transmissive type (i.e., has a transmissive patterning device). However, in general, it may also be of a reflective type, for example (with a reflective patterning device). The apparatus may employ a different kind of patterning device to classic mask; examples include a programmable mirror array or LCD matrix.

The source SO (e.g., a mercury lamp or excimer laser, LPP (laser produced plasma) EUV source) produces a beam of radiation. This beam is fed into an illumination system (illuminator) IL, either directly or after having traversed conditioning apparatuses, such as a beam expander Ex, for example. The illuminator IL may comprise adjusting device AD for setting the outer and/or inner radial extent (commonly referred to as σ-outer and σ-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

In some embodiments, source SO may be within the housing of the lithographic projection apparatus (as is often the case when source SO is a mercury lamp, for example), but that it may also be remote from the lithographic projection apparatus, the radiation beam that it produces being led into the apparatus (e.g., with the aid of suitable directing mirrors); this latter scenario can be the case when source SO is an excimer laser (e.g., based on KrF, ArF or F2 lasing).

The beam PB can subsequently intercept patterning device MA, which is held on a patterning device table MT. Having traversed patterning device MA, the beam B can pass through the lens PL, which focuses beam B onto target portion C of substrate W. With the aid of the second positioning apparatus (and interferometric measuring apparatus IF), the substrate table WT can be moved accurately, e.g., so as to position different target portions C in the path of beam PB. Similarly, the first positioning apparatus can be used to accurately position patterning device MA with respect to the path of beam B, e.g., after mechanical retrieval of the patterning device MA from a patterning device library, or during a scan. In general, movement of the object tables MT, WT can be realized with the aid of a long-stroke module (coarse positioning) and a short-stroke module (fine positioning). However, in the case of a stepper (as opposed to a step-and-scan tool) patterning device table MT may just be connected to a short stroke actuator, or may be fixed.

The depicted tool can be used in two different modes, step mode and scan mode. In step mode, patterning device table MT is kept essentially stationary, and an entire patterning device image is projected in one go (i.e., a single “flash”) onto a target portion C. Substrate table WT can be shifted in the x and/or y directions so that a different target portion C can be irradiated by beam PB.

In scan mode, essentially the same scenario applies, except that a given target portion C is not exposed in a single “flash.” Instead, patterning device table MT is movable in a given direction (the so-called “scan direction”, e.g., the y direction) with a speed v, so that projection beam B is caused to scan over a patterning device image; concurrently, substrate table WT is simultaneously moved in the same or opposite direction at a speed V=Mv, in which M is the magnification of the lens PL (typically, M=1/4 or 1/5). In this manner, a relatively large target portion C can be exposed, without having to compromise on resolution.

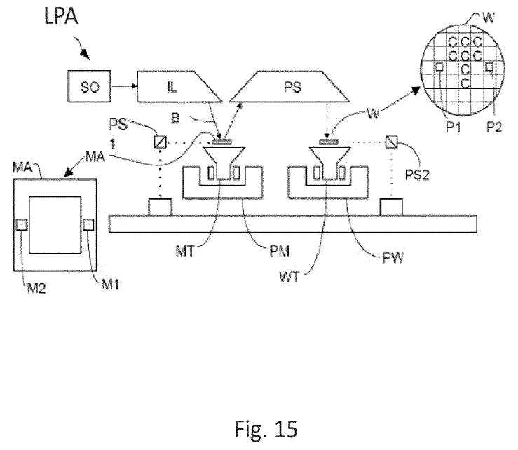

FIG. 15 is a schematic diagram of another lithographic projection apparatus (LPA), according to an embodiment of the present disclosure.

LPA can include source collector module SO, illumination system (illuminator) IL configured to condition a radiation beam B (e.g., EUV radiation), support structure MT, substrate table WT, and projection system PS.

Support structure (e.g., a patterning device table) MT can be constructed to support a patterning device (e.g., a mask or a reticle) MA and connected to a first positioner PM configured to accurately position the patterning device;

Substrate table (e.g., a wafer table) WT can be constructed to hold a substrate (e.g., a resist coated wafer) W and connected to a second positioner PW configured to accurately position the substrate.

Projection system (e.g., a reflective projection system) PS can be configured to project a pattern imparted to the radiation beam B by patterning device MA onto a target portion C (e.g., comprising one or more dies) of the substrate W.

As here depicted, LPA can be of a reflective type (e.g., employing a reflective patterning device). It is to be noted that because most materials are absorptive within the EUV wavelength range, the patterning device may have multilayer reflectors comprising, for example, a multi-stack of molybdenum and silicon. In one example, the multi-stack reflector has a 40 layer pairs of molybdenum and silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Illuminator IL can receive an extreme ultraviolet radiation beam from source collector module SO. Methods to produce EUV radiation include, but are not necessarily limited to, converting a material into a plasma state that has at least one element, e.g., xenon, lithium or tin, with one or more emission lines in the EUV range. In one such method, often termed laser produced plasma (“LPP”) the plasma can be produced by irradiating a fuel, such as a droplet, stream or cluster of material having the line-emitting element, with a laser beam. Source collector module SO may be part of an EUV radiation system including a laser for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation.

In such cases, the laser may not be considered to form part of the lithographic apparatus and the radiation beam can be passed from the laser to the source collector module with the aid of a beam delivery system comprising, for example, suitable directing mirrors and/or a beam expander. In other cases, the source may be an integral part of the source collector module, for example when the source is a discharge produced plasma EUV generator, often termed as a DPP source.

Illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B can be incident on the patterning device (e.g., mask) MA, which is held on the support structure (e.g., patterning device table) MT, and is patterned by the patterning device. After being reflected from the patterning device (e.g., mask) MA, the radiation beam B passes through the projection system PS, which focuses the beam onto a target portion C of the substrate W. With the aid of the second positioner PW and position sensor PS2 (e.g., an interferometric device, linear encoder or capacitive sensor), the substrate table WT can be moved accurately, e.g., so as to position different target portions C in the path of radiation beam B. Similarly, the first positioner PM and another position sensor PS1 can be used to accurately position the patterning device (e.g., mask) MA with respect to the path of the radiation beam B. Patterning device (e.g., mask) MA and substrate W may be aligned using patterning device alignment marks M1, M2 and substrate alignment marks P1, P2.

The depicted apparatus LPA could be used in at least one of the following modes, step mode, scan mode, and stationary mode.

In step mode, the support structure (e.g., patterning device table) MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed.

In scan mode, the support structure (e.g., patterning device table) MT and the substrate table WT are scanned synchronously while a pattern imparted to the radiation beam is projected onto target portion C (i.e. a single dynamic exposure). The velocity and direction of substrate table WT relative to the support structure (e.g., patterning device table) MT may be determined by the (de-)magnification and image reversal characteristics of the projection system PS.

In stationary mode, the support structure (e.g., patterning device table) MT is kept essentially stationary holding a programmable patterning device, and substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array.

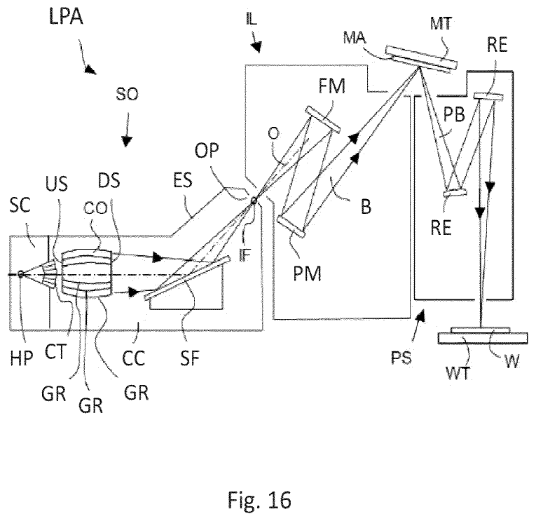

FIG. 16 is a detailed view of the lithographic projection apparatus, according to an embodiment of the present disclosure.

As shown, LPA can include the source collector module SO, the illumination system IL, and the projection system PS. The source collector module SO is constructed and arranged such that a vacuum environment can be maintained in an enclosing structure ES of the source collector module SO. An EUV radiation emitting hot plasma HP may be formed by a discharge produced plasma source. EUV radiation may be produced by a gas or vapor, for example Xe gas, Li vapor or Sn vapor in which the hot plasma HP is created to emit radiation in the EUV range of the electromagnetic spectrum. The hot plasma HP is created by, for example, an electrical discharge causing at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma HP is passed from a source chamber SC into a collector chamber CC via an optional gas barrier or contaminant trap CT (in some cases also referred to as contaminant barrier or foil trap) which is positioned in or behind an opening in source chamber SC. The contaminant trap CT may include a channel structure. Contamination trap CT may also include a gas barrier or a combination of a gas barrier and a channel structure. The contaminant trap or contaminant barrier CT further indicated herein at least includes a channel structure, as known in the art.

The collector chamber CC may include a radiation collector CO which may be a so-called grazing incidence collector. Radiation collector CO has an upstream radiation collector side US and a downstream radiation collector side DS. Radiation that traverses radiation collector CO can be reflected off a grating spectral filter SF to be focused in a virtual source point IF along the optical axis indicated by the dot-dashed line ‘O’. The virtual source point IF can be referred to as the intermediate focus, and the source collector module can be arranged such that the intermediate focus IF is located at or near an opening OP in the enclosing structure ES. The virtual source point IF is an image of the radiation emitting plasma HP.

Subsequently the radiation traverses the illumination system IL, which may include a facetted field mirror device FM and a facetted pupil mirror device pm arranged to provide a desired angular distribution of the radiation beam B, at the patterning device MA, as well as a desired uniformity of radiation amplitude at the patterning device MA. Upon reflection of the beam of radiation B at the patterning device MA, held by the support structure MT, a patterned beam PB is formed and the patterned beam PB is imaged by the projection system PS via reflective elements RE onto a substrate W held by the substrate table WT.

More elements than shown may generally be present in illumination optics unit IL and projection system PS. The grating spectral filter SF may optionally be present, depending upon the type of lithographic apparatus. Further, there may be more mirrors present than those shown in the figures, for example there may be 1-6 additional reflective elements present in the projection system PS.

Collector optic CO can be a nested collector with grazing incidence reflectors GR, just as an example of a collector (or collector mirror). The grazing incidence reflectors GR are disposed axially symmetric around the optical axis O and a collector optic CO of this type may be used in combination with a discharge produced plasma source, often called a DPP source.

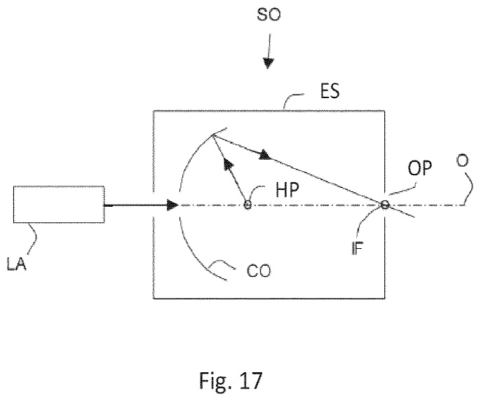

FIG. 17 is a detailed view of source collector module SO of lithographic projection apparatus LPA, according to an embodiment of the present disclosure.

Source collector module SO may be part of an LPA radiation system. A laser LA can be arranged to deposit laser energy into a fuel, such as xenon (Xe), tin (Sn) or lithium (Li), creating the highly ionized plasma HP with electron temperatures of several 10's of eV. The energetic radiation generated during de-excitation and recombination of these ions is emitted from the plasma, collected by a near normal incidence collector optic CO and focused onto the opening OP in the enclosing structure ES.

The concepts disclosed herein may simulate or mathematically model any generic imaging system for imaging sub wavelength features, and may be especially useful with emerging imaging technologies capable of producing increasingly shorter wavelengths. Emerging technologies already in use include EUV (extreme ultraviolet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-50 nm by using a synchrotron or by hitting a material (either solid or a plasma) with high energy electrons in order to produce photons within this range.

Embodiments of the present disclosure can be further described by the following clauses.

1. A method for determining a mask pattern for use with a lithographic process, the method comprising:
assigning locations of two-dimensional elements based on a target pattern;
associating the two-dimensional elements based on association criteria to form a cluster that represents a mask feature; and
adjusting the two-dimensional elements of the cluster to vary the mask feature.

2. The method of clause 1, wherein the adjusting is based on a simulation associated with the lithography process.

3. The method of clause 1, wherein the adjusting is based on geometric properties of the mask pattern and based on rules prescribed for OPC.

4. The method of clause 1, further comprising generating a contour of the cluster based on the two-dimensional elements.

5. The method of clause 4, wherein the contour is an outer contour of the cluster that corresponds to an outer edge of the mask feature.

6. The method of clause 4, wherein the contour is an inner contour of the cluster that corresponds to an inner edge of the mask feature.

7. The method of clause 4, further comprising:
generating sub-areas of the contour by applying a polygon offsetting operation to pairs of the associated two-dimensional elements.
computing the union of the sub-areas, wherein the contour is the union of the sub-areas.

8. The method of clause 4, further comprising manufacturing a mask from the mask pattern that includes the contour generated from the adjusted two-dimensional elements.

9. The method of clause 4, wherein the contour is at least partially a prescribed distance from the locations of the two-dimensional elements.

10. The method of clause 9, wherein the contour is entirely at least the prescribed distance from the locations of the two-dimensional elements.

11. The method of clause 9, wherein the prescribed distance is based on an MRC rule for a minimum width of the mask feature.

12. The method of clause 9, wherein at least a portion of the contour violates an MRC rule.

13. The method of clause 1, wherein geometry of the two-dimensional elements are defined based on one or more mask rule compliance (MRC) rules.

14. The method of clause 13, wherein a dimension parameter of the two-dimensional element is selected to be a minimum width specified by the MRC rules.

15. The method of clause 13, wherein the one or more MRC rules include a minimum space requirement, the association criteria comprising connecting a second two-dimensional element into the cluster when a distance between a second contour for the second two-dimensional element and the contour for the two-dimensional elements in the cluster is less than the minimum space requirement.

16. The method of clause 1, further comprising modifying the cluster of the two-dimensional elements into one or more modified clusters.

17. The method of clause 16, the one or more modified clusters formed based on MRC rules.

18. The method of clause 16, the operations further comprising:
modifying the cluster by dissociating one of the two-dimensional elements from the cluster; and
modifying the contour based on the modified cluster.

19. The method of clause 16, the operations further comprising:
modifying the cluster by associating a two-dimensional element from another cluster with the cluster; and
modifying the contour based on the modified cluster.

20. The method of clause 1, the adjusting comprising optimizing the mask pattern by moving a location of one or more of the two-dimensional elements.

21. The method of clause 1, the adjusting comprising optimizing the mask pattern by adjusting a size or a shape of one or more of the two-dimensional elements.

22. The method of clause 1, the associating further comprising associating a two-dimensional element that is within a prescribed distance from other two-dimensional elements.

23. The method of clause 22, the associating or adjusting further comprising dissociating a two-dimensional element from the two-dimensional elements of the cluster and associating the two-dimensional element with a two-dimensional element in a second cluster.

24. The method of clause 1, further comprising computing a cost function that quantifies an evaluation of the mask pattern, wherein the adjusting of the two-dimensional elements is based on the cost function.

25. The method of clause 24, wherein the cost function does not include any terms based on MRC rules.

26. The method of clause 1, wherein each of the two-dimensional elements are circular.

27. The method of clause 1, wherein each of the two-dimensional elements is elliptical.

28. The method of clause 1, wherein each of the two-dimensional elements are the same size.

29. The method of clause 1, wherein each of the two-dimensional elements defines a non-zero area.

30. The method of clause 1, wherein each of the two-dimensional elements is a polygon.

31. The method of clause 1, wherein each of the two-dimensional elements defines an enclosed or semi-enclosed area.

32. The method of clause 5, further comprising performing corner rounding on the outer contour.

33. The method of clause 32, wherein the corner rounding comprises performing spline interpolation between two points on either side of a corner.

34. The method of clause 1, the operations further comprising:
generating consistent clusters by replicating the cluster in the mask pattern; and
adjusting corresponding two-dimensional elements in the consistent clusters.

35. The method of clause 34, the adjusting of the consistent clusters comprising:
identifying a boundary two-dimensional element across a boundary between a first mask patch and a second mask patch;
wherein adjusting the two-dimensional elements excludes adjusting the boundary two-dimensional element.

36. The method of clause 34, the adjusting of the consistent clusters comprising:
designating the two-dimensional elements that are within a threshold distance of a boundary of a first mask patch and a second mask patch as priority two-dimensional elements; and
wherein adjusting the two-dimensional elements excludes adjusting any priority two-dimensional elements.

37. The method of clause 35, further comprising storing, in computer memory for later recall, the priority two-dimensional elements.

38. The method of clause 35, further comprising replacing one or more of the two-dimensional elements within the threshold distance to the boundary with priority two-dimensional elements.

39. The method of clause 1, further comprising:
receiving the mask pattern;
generating consistent clusters by replicating the cluster in the mask pattern, wherein the adjusting includes adjusting corresponding two-dimensional elements in the consistent clusters;
designating the two-dimensional elements that are within a threshold distance of a boundary of a first mask patch and a second mask patch as priority two-dimensional elements;
replacing one or more of the two-dimensional elements close to the boundary with priority two-dimensional elements recalled from computer memory; and
generating an adjusted mask pattern based on the two-dimensional elements in the consistent clusters, wherein adjusting the two-dimensional elements excludes adjusting any priority two-dimensional elements.

40. A non-transitory computer readable medium having instructions recorded thereon for determining a mask pattern for use with a lithographic process, the instructions when executed by a computer having at least one programmable processor cause operations comprising, the operations as in any of clauses 1-39.

41. A system for determining a mask pattern for use with a lithographic process, the system comprising:
at least one programmable processor; and
a non-transitory computer readable medium having instructions recorded thereon, the instructions when executed by a computer having the at least one programmable processor cause operations as in any of clauses 1-39.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

The combinations and sub-combinations of the elements disclosed herein constitute separate embodiments and are provided as examples only. Also, the descriptions above are intended to be illustrative, not limiting. Thus, it will be apparent to one skilled in the art that modifications may be made as described without departing from the scope of the claims set out below.

1. A method for determining a mask pattern for use with a lithographic process, the method comprising:
assigning, by a hardware computer system, locations of two-dimensional elements based on a target pattern;
associating, by the hardware computer system and based on association criteria, the two-dimensional elements to form a cluster that represents a mask feature of the mask pattern; and
adjusting, by the hardware computer system, the two-dimensional elements of the cluster to vary the mask feature.

2. The method of claim 1, wherein the adjusting is based on a simulation of the lithography process to optimize the mask pattern.

3. The method of claim 1, further comprising generating a contour of the cluster based on the two-dimensional elements, wherein the contour is an outer contour of the cluster that corresponds to an outer edge of the mask feature or an inner contour of the cluster that corresponds to an inner edge of the mask feature.

4. The method of claim 3, further comprising:
generating sub-areas of the contour by applying a polygon offsetting operation to pairs of the associated two-dimensional elements; and
computing the union of the sub-areas, wherein the contour defines the union of the sub-areas.

5. The method of claim 3, wherein the contour is set at least partially a prescribed distance from the locations of the two-dimensional elements.

6. The method of claim 1, wherein geometry of the two-dimensional elements are defined based on one or more mask rule compliance (MRC) rules.

7. The method of claim 6, wherein the one or more MRC rules include a minimum space requirement, the association criteria comprising connecting a further two-dimensional element into the cluster when a distance between a contour for the further two-dimensional element and the contour for the two-dimensional elements in the cluster is less than the minimum space requirement.

8. The method of claim 1, further comprising modifying the cluster of the two-dimensional elements into one or more modified clusters.

9. The method of claim 8, wherein the one or more modified clusters are formed based on one or more MRC rules and/or a simulation associated with the lithography process.

10. The method of claim 8, wherein the modifying the cluster comprises modifying the cluster by dissociating one of the two-dimensional elements from the cluster or by associating a two-dimensional element from another cluster with the cluster; and further comprising modifying the contour based on the modified cluster.

11. The method of claim 1, wherein the adjusting comprises optimizing the mask pattern by adjusting a size or a shape of one or more of the two-dimensional elements.

12. The method of claim 1, wherein each of the two-dimensional elements defines an enclosed or semi-enclosed area, wherein each of the two-dimensional elements is circular, elliptical, or a polygon.

13. The method of claim 1, further comprising:
generating consistent clusters for repeating features by replicating the cluster in the mask pattern; and
adjusting corresponding two-dimensional elements in the consistent clusters.

14. The method of claim 13, wherein the adjusting of the consistent clusters comprises identifying a boundary two-dimensional element across a boundary between a first mask patch and a second mask patch; and
wherein adjusting the two-dimensional elements excludes adjusting the boundary two-dimensional element.

15. The method of claim 13, wherein the adjusting of the consistent clusters comprises designating the two-dimensional elements that are within a threshold distance of a boundary of a first mask patch and a second mask patch as priority two-dimensional elements; and
wherein adjusting the two-dimensional elements excludes adjusting any priority two-dimensional elements.

16. The method of claim 14, further comprising replacing one or more of the two-dimensional elements within the threshold distance to the boundary with priority two-dimensional elements.

17. A computer product comprising a non-transitory computer-readable medium comprising instructions therein, the instructions, when executed by a computer system, configured to cause the computer system to at least:
assign locations of two-dimensional elements based on a target pattern;
associate, based on association criteria, the two-dimensional elements to form a cluster that represents a mask feature of a mask pattern for use with a lithographic process; and
adjust the two-dimensional elements of the cluster to vary the mask feature.

18. The computer product of claim 17, wherein the instructions configured to cause the computer system to adjust the two-dimensional elements of the cluster are further configured to cause the computer system to adjust the two-dimensional elements of the cluster based on a simulation of the lithography process to optimize the mask pattern.

19. The computer product of claim 17, wherein the instructions are further configured to cause the computer system to generate a contour of the cluster based on the two-dimensional elements, wherein the contour is an outer contour of the cluster that corresponds to an outer edge of the mask feature or an inner contour of the cluster that corresponds to an inner edge of the mask feature.

20. The computer product of claim 17, wherein the instructions are further configured to cause the computer system to modify the cluster of the two-dimensional elements into one or more modified clusters.
